(19) United States
(12) Patent Application Publication
(10) Pub. No.: US 2006/0046343 A1
(43) Pub. Date: Mar. 2, 2006

(54) Method of fabricating organic light emitting display

(76) Inventors: Myung-Won Song, Suwon-si (KR); Seong-Taek Lee, Suwon-si (KR); Mu-Hyun Kim, Suwon-si (KR); Byung-Doo Chin, Seongnam-si (KR)

Correspondence Address: MCGUIREWOODS, LLP, 1750 TYSONS BLVD, SUITE 1800, MCLEAN, VA, 22102, US

(21) Appl. No.: 11/017,658

(22) Filed: Dec. 22, 2004

(30) Foreign Application Priority Data
Aug. 30, 2004 (KR) 2004-68773

(51) Int. Cl. H01L 29/15

(52) U.S. Cl. 438/99

(57) ABSTRACT

A method of fabricating an organic light emitting display is provided. The method includes: preparing a base substrate for a donor substrate; cleaning the base substrate; forming a transfer layer on the cleaned base substrate; and patterning the transfer layer by making the donor substrate opposite to a substrate on which a pixel electrode is formed.

### CROSS-REFERENCE TO RELATED APPLICATION

This application claims priority to and the benefit of Korean Patent Application No. 2004-68773, filed Aug. 30, 2004, the disclosure of which is incorporated herein by reference in its entirety.

### BACKGROUND OF THE INVENTION

1. Field of the Invention

The present invention relates to a method of fabricating an organic light emitting display, and more particularly, to a method of fabricating an organic light emitting display using a donor substrate fabricated through a cleaning process of a base substrate.

2. Description of the Related Art

Among flat panel displays, an organic light emitting display has an advantage as a moving picture display medium regardless of its size due to a fast response speed of 1 ms or less, low power consumption, and an unproblematic viewing angle resulting from an emissive display. Further, the organic light emitting display is drawing attention as a next-generation flat panel display due to a capability of low-temperature fabrication as well as a simple fabricating process based on an existing semiconductor process technique.

The organic light emitting display may be generally divided into two types according to a material and a process using as an organic light emitting element: one for a polymer type using a wet process and the other for a small molecular type using a deposition process.

The polymer organic light emitting element is fabricated by depositing an organic layer including an emission layer on a substrate having a pixel electrode using an inkjet printing method or a spin coating method, and by forming a counter electrode.

Further, the small molecular organic light emitting element is fabricated by depositing an organic layer including an emission layer on a substrate having a pixel electrode by means of a deposition process, and by forming a counter electrode.

Among methods of patterning the polymer or small molecular emission layer, the inkjet printing method is limited to a material for the organic layers other than the emission layer, and has trouble that a structure for inkjet printing should be formed on the substrate.

Further, the method of patterning the emission layer by the deposition process has difficulty in fabricating a large-sized display due to use of a metal mask.

As a technique capable of replacing the foregoing patterning methods, a laser induced thermal imaging (LITI) method is currently developed.

The LITI method refers to a method of converting laser emitted from a light source into thermal energy, transferring a pattern forming material to a target substrate by means of the thermal energy, and forming a desired pattern. For the purpose of this method, there are required a donor substrate on which a transfer layer is formed, a light source, and a substrate to be transferred.

In general, the donor substrate for laser induced thermal imaging is fabricated by forming a light-heat conversion layer and a transfer layer on a base substrate. Therefore, in order to protect the light-heat conversion layer and the transfer layer as well as to perform an effective laser induced thermal imaging process, the base substrate should not be contaminated.

FIG. 1 is a photograph showing that contaminants are generated on a base substrate. Such contaminants A are generated in the process of transporting the base substrate or fabricating the donor substrate. The contaminants A may remain on an emission layer and a pixel electrode during the subsequent LITI process. The contaminants A may cause a defect of the display such as a spot of or a pixel failure in an emission region, resulting in deterioration in characteristics of the display.

### SUMMARY OF THE INVENTION

The present invention, therefore, solves aforementioned problems associated with conventional devices by removing contaminants which are present on a base substrate in the process of preparing the base substrate for a donor substrate to thereby prevent a failure of the donor substrate resulting from the contaminants during a laser induced thermal imaging process, as well as to prevent a defect of an organic light emitting display fabricated by using the donor substrate.

In an exemplary embodiment of the present invention, a method of fabricating an organic light emitting display includes: preparing a base substrate for a donor substrate; cleaning the base substrate; forming a transfer layer on the cleaned base substrate; and patterning the transfer layer by making the donor substrate opposite to a substrate on which a pixel electrode is formed.

The method may further include cutting the base substrate, and performing a secondary cleaning process with respect to the cut base substrate.

The method may further include framing the cleaned base substrate.

In another exemplary embodiment of the present invention, a method of fabricating a donor substrate includes: preparing a base substrate; cleaning the base substrate; and forming a transfer layer on the cleaned base substrate.

### BRIEF DESCRIPTION OF THE DRAWINGS

The above and other features of the present invention will be described in reference to certain exemplary embodiments thereof with reference to the attached drawings in which:

FIG. 1 is a photograph showing that contaminants are generated on a base substrate;

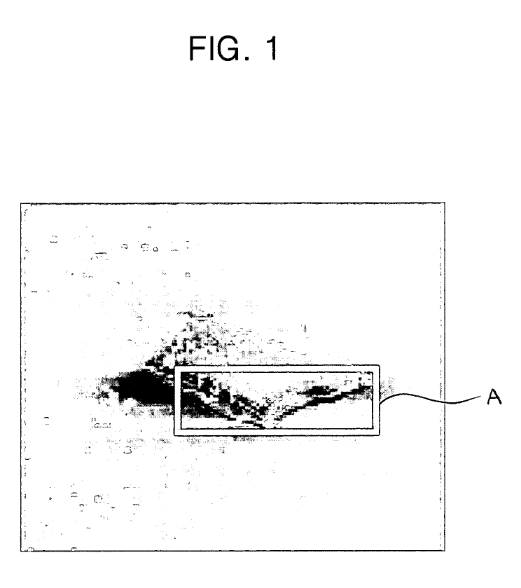

FIG. 2 is a process flow chart showing a process of fabricating a donor substrate for laser induced thermal imaging in accordance with an embodiment of the present invention; and

FIG. 3 is a cross-sectional view of a unit pixel of an organic light emitting display, for showing a process of performing a laser induced thermal imaging method with respect to a donor substrate.

### DETAILED DESCRIPTION OF THE INVENTION

Hereinafter, exemplary embodiments of the present invention will now be described in detail with reference to the accompanying drawings. The embodiments disclosed hereinafter are to be provided as examples such that the spirit of the present invention can be fully conveyed to those skilled in the art. Therefore, the present invention may be embodied in different forms without being limited to the embodiments set forth hereinafter. In the drawings, the thickness of layers and regions are exaggerated for clarity. Like numbers refer to like elements throughout the specification.

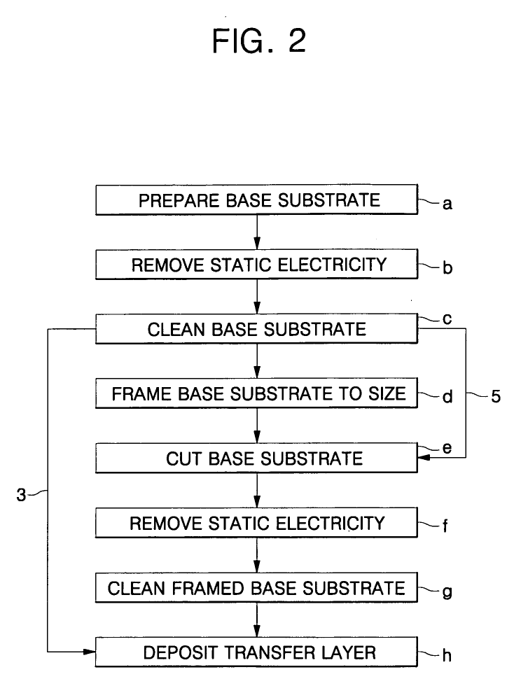

FIG. 2 is a process flow chart showing a process of fabricating a donor substrate for laser induced thermal imaging in accordance with an embodiment of the present invention.

Referring to FIG. 2, the donor substrate for laser induced thermal imaging of the present invention is completed through the processes of preparing a base substrate (step a), removing static electricity existing on the base substrate (step b), cleaning the base substrate from which the static electricity has been removed (step c), and depositing a desired layer on the base substrate.

To be more specific, the base substrate is prepared (step a).

The base substrate may have a sheet type. The substrate having the sheet type may be a solid substrate, for example, of metal, glass or so forth.

Alternatively, the base substrate may have a roll type. The substrate having the roll type may be a flexible film.

The static electricity is removed from the base substrate by using a charger (step b). The process of removing the static electricity allows foreign materials existing on the base substrate to be primarily removed.

The base substrate from which the static electricity has been removed is cleaned (step c).

The base substrate may be cleaned by a wet cleaning process.

The wet cleaning process may be carried out by using deionized water or isopropyl alcohol. For example, a batch in which the foregoing solution is contained is installed in equipment for fabricating the donor substrate, and the base substrate is adapted to pass through the batch during transportation. In this process, the wet cleaning process can be performed.

Alternatively, the base substrate may be cleaned by a dry cleaning process.

The dry cleaning process may employ a technique of using carbon dioxide (CO₂), an ultrasonic wave, or a laser pulse wave.

The technique of using carbon dioxide (CO₂) is to remove the contaminants by sublimating a dry ice, a solid of CO₂, and at the same striking the sublimated material onto the base substrate. In other words, the technique of using carbon dioxide (CO₂) may be referred to as a cleaning mechanism using physical and thermodynamic forces of the dry ice which collides with the base substrate and then is subjected to expansion.

The technique of using a laser pulse wave may be either to apply the laser pulse wave onto a transfer layer of the donor substrate to remove particles existing on the substrate, or to vibrate air around the donor substrate using the laser pulse wave to float and remove particles existing on the substrate. In this case, the floated particles may be removed by blowing or suction.

The technique of using an ultrasonic wave is to inject a high-speed ultrasonic gas onto a transfer layer of the donor substrate to remove particles by means of separation and suction.

Thus, the contaminants existing on the base substrate due to an external environment or in the course of performing the process can be removed by the wet or dry cleaning process. As a result, it is possible not only to prevent a defect of the display, such as a spot or a pixel failure in an emission region, which is caused by the contaminants remaining on the emission layer and the pixel electrode during the laser induced thermal imaging process, but also to improve characteristics of the display.

The cleaned base substrate may be framed (step d) and cut off (step e). Here, the framed base substrate may be further subjected to a secondary cleaning process (step g). Before the secondary cleaning process, the framed base substrate may be subjected to a removing process of static electricity (step f). Thus, the secondary cleaning process may be performed after removing the contaminants attached by the static electricity first.

The secondary cleaning process of the framed base substrate may use either the wet cleaning process or the dry cleaning process (step g). In the wet cleaning process, deionized water or isopropyl alcohol may be used. Further, the dry cleaning process may employ a technique of using carbon dioxide (CO₂), an ultrasonic wave, or a laser pulse wave.

Therefore, the contaminants caused by the framing and cutting processes of the base substrate can be removed by the secondary cleaning process. The base substrate may have a more clean surface state.

Alternatively, the framing process may be omitted.

Specifically, in the case of the roll type of flexible substrate, the transfer layer may be deposited by an in-line process 3 without the cutting process after the cleaning process (step h).

Further, in the case of the sheet type of solid substrate, the base substrate is cut by another in-line process 5 without the framing process (step e), and after performing the foregoing secondary cleaning process, the transfer layer may be deposited (step h).

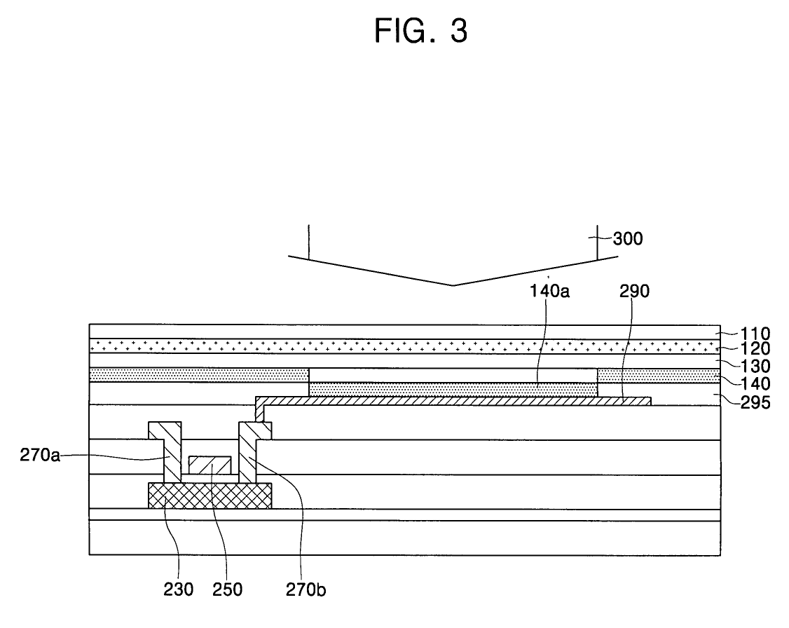

FIG. 3 is a cross-sectional view, of a unit pixel of an organic light emitting display, for showing a process of performing a laser thermal transfer technique with respect to a donor substrate.

Referring to FIG. 3, a light-heat conversion layer 120 is formed on a base substrate 110 by the above-mentioned processes. A transfer layer 140 is formed on the light-heat conversion layer 120. As a result, a donor substrate 100 is completed.

The light-heat conversion layer 120 is formed of a light absorbing material having a property of absorbing the light of a region from infrared rays to visible rays. The light-heat conversion layer 120 is any one of an organic layer, a metal layer and their composite layer, which contains a laser absorbing material.

The light-heat conversion layer 120 serves to convert a laser irradiated at a laser irradiator. And, the thermal energy changes an adhesion between the transfer layer 140 and the light-heat conversion layer 120, thereby serving to transfer the transfer layer onto the substrate to be transferred.

The transfer layer 140 is formed on the light-heat conversion layer 120. In order to prevent a damage of the transfer material and effectively adjust the adhesion between the transfer layer 140 and the donor substrate, a buffer layer 130 may be interposed between the light-heat conversion layer 120 and the transfer layer 140.

The transfer layer 140 may be an emission layer of the organic light emitting diode.

Further, the transfer layer 140 of the donor substrate may further include at least one selected from the group consisting of a hole injection layer, a hole transport layer, a hole blocking layer and an electron injection layer.

The donor substrate 100 through the fabricating process including the cleaning process is located on the substrate on which a thin film transistor and a pixel electrode 290 are formed.

To be more specific, the thin film transistor made of a semiconductor layer 230, a gate electrode 250, a source electrode 270a and a drain electrode 270b is formed on the substrate 210. The pixel electrode 290 is formed, which is connected with the source electrode 270a or drain electrode 270b of the thin film transistor and is exposed by a pixel defining layer 295.

When a laser induced thermal imaging process by laser 300 is carried out on the donor substrate 100, a transfer layer 140a is transferred onto the exposed pixel electrode 290, so that the emission layer is patterned.

Since the transfer layer 140 is formed on the base substrate 110 from which the contaminants are removed by the cleaning process, as set forth above, it is possible to prevent the defect of the organic light emitting display, such as the spot or the pixel failure in the emission region.

The method of fabricating the donor substrate according to the present invention can prevent a failure of the donor substrate caused by the contaminants during the laser induced thermal imaging process by removing the contaminants existing on the base substrate for the donor substrate. Therefore, the organic light emitting display fabricated using the donor substrate can improve the failure of the pixel.

Although the present invention has been described with reference to certain exemplary embodiments thereof, it will be understood by those skilled in the art that a variety of modifications and variations may be made to the present invention without departing from the spirit or scope of the present invention defined in the appended claims, and their equivalents.

What is claimed is:

1. A method of fabricating an organic light emitting display, comprising:
preparing a base substrate for a donor substrate;
cleaning the base substrate;
forming a transfer layer on the cleaned base substrate; and
patterning the transfer layer by making the donor substrate opposite to a substrate on which a pixel electrode is formed.

2. The method as claimed in claim 1, further comprising removing static electricity using a charger before cleaning the base substrate.

3. The method as claimed in claim 1, wherein cleaning the base substrate is performed by a wet cleaning process.

4. The method as claimed in claim 3, wherein the wet cleaning process makes use of any one of deionized water and isopropyl alcohol.

5. The method as claimed in claim 1, wherein cleaning the base substrate is performed by a dry cleaning process.

6. The method as claimed in claim 5, wherein the dry cleaning process employs any one of a technique of using carbon dioxide (CO₂), a technique of using an ultrasonic wave, and a technique of using a laser pulse wave.

7. The method as claimed in claim 1, further comprising:
cutting the base substrate; and
performing a secondary cleaning process with respect to the cut base substrate.

8. The method as claimed in claim 7, wherein the secondary cleaning process with respect to the cut base substrate is performed by a wet cleaning process.

9. The method as claimed in claim 8, wherein the wet cleaning process makes use of any one of deionized water and isopropyl alcohol.

10. The method as claimed in claim 7, wherein the secondary cleaning process with respect to the cut base substrate is performed by a dry cleaning process.

11. The method as claimed in claim 10, wherein the dry cleaning process employs any one of a technique of using carbon dioxide (CO₂), a technique of using an ultrasonic wave, and a technique of using a laser pulse wave.

12. The method as claimed in claim 1, further comprising framing the cleaned base substrate.

13. The method as claimed in claim 12, further comprising performing a second cleaning process with respect to the framed base substrate.

14. The method as claimed in claim 13, wherein the second cleaning process with respect to the framed base substrate is performed by a wet cleaning process.

15. The method as claimed in claim 14, wherein the wet cleaning process makes use of any one of deionized water and isopropyl alcohol.

16. The method as claimed in claim 12, wherein the secondary cleaning process with respect to the framed base substrate is performed by a dry cleaning process.

17. The method as claimed in claim 16, wherein the dry cleaning process employs any one of a technique of using carbon dioxide (CO₂), a technique of using an ultrasonic wave, and a technique of using a laser pulse wave.

18. The method as claimed in claim 1, wherein the transfer layer is an emission layer of an organic light emitting element.

19. The method as claimed in claim 18, wherein the transfer layer further includes at least one selected from a group consisting of a hole injection layer, a hole transport layer, a hole blocking layer and an electron injection layer.

20. A method of fabricating a donor substrate, comprising:
preparing a base substrate;
cleaning the base substrate; and
forming a transfer layer on the cleaned base substrate.

21. The method as claimed in claim 20, further comprising removing static electricity using a charger before cleaning the base substrate.

22. The method as claimed in claim 20, wherein cleaning the base substrate is performed by a wet cleaning process.

23. The method as claimed in claim 22, wherein the wet cleaning process makes use of any one of deionized water and isopropyl alcohol.

24. The method as claimed in claim 20, wherein cleaning the base substrate is performed by a dry cleaning process.

25. The method as claimed in claim 24, wherein the dry cleaning process employs any one of a technique of using carbon dioxide (CO₂), a technique of using an ultrasonic wave, and a technique of using a laser pulse wave.

26. The method as claimed in claim 20, further comprising:
cutting the base substrate; and
performing a secondary cleaning process with respect to the cut base substrate.

27. The method as claimed in claim 26, wherein the secondary cleaning process with respect to the cut base substrate is performed by a wet cleaning process.

28. The method as claimed in claim 27, wherein the wet cleaning process makes use of any one of deionized water and isopropyl alcohol.

29. The method as claimed in claim 26, wherein the secondary cleaning process with respect to the cut base substrate is performed by a dry cleaning process.

30. The method as claimed in claim 29, wherein the dry cleaning process employs any one of a technique of using carbon dioxide (CO₂), a technique of using an ultrasonic wave, and a technique of using a laser pulse wave.

31. The method as claimed in claim 20, further comprising framing the cleaned base substrate.

32. The method as claimed in claim 31, further comprising performing a second cleaning process with respect to the framed base substrate.

33. The method as claimed in claim 32, wherein the second cleaning process with respect to the framed base substrate is performed by a wet cleaning process.

34. The method as claimed in claim 33, wherein the wet cleaning process makes use of any one of deionized water and isopropyl alcohol.

35. The method as claimed in claim 31, wherein the secondary cleaning process with respect to the framed base substrate is performed by a dry cleaning process.

36. The method as claimed in claim 35, wherein the dry cleaning process employs any one of a technique of using carbon dioxide (CO₂), a technique of using an ultrasonic wave, and a technique of using a laser pulse wave.

37. The method as claimed in claim 20, wherein the transfer layer is an emission layer of an organic light emitting element.

38. The method as claimed in claim 37, wherein the transfer layer further includes at least one selected from a group consisting of a hole injection layer, a hole transport layer, a hole blocking layer and an electron injection layer.
